(19) United States
(12) Patent Application Publication
(10) Pub. No.: US 2015/0228733 A1
(43) Pub. Date: Aug. 13, 2015

(54) Array Substrate, Manufacturing Method Thereof, and Display Device

(71) Applicants: BOE TECHNOLOGY GROUP CO., LTD., Beijing (CN); BEIJING BOE DISPLAY TECHNOLOGY CO., LTD., Beijing (CN)

(72) Inventors: Jinchao Bai, Beijing (CN); Yusheng Xi, Beijing (CN); Zongjie Guo, Beijing (CN); Xiangqian Ding, Beijing (CN); Yao Liu, Beijing (CN); Liangliang Li, Beijing (CN)

(21) Appl. No.: 14/308,129

(22) Filed: Jun. 18, 2014

(30) Foreign Application Priority Data
Feb. 12, 2014 (CN) 201410048499.3

(51) Int. Cl. H01L 29/417; H01L 29/66; H01L 21/768; H01L 21/02; H01L 21/32; H01L 21/311; H01L 27/12; H01L 29/786; H01L 21/306

(52) U.S. Cl. CPC H01L 29/4175; H01L 29/78669; H01L 29/66765; H01L 21/76897; H01L 21/30604; H01L 21/32; H01L 21/31111; H01L 27/124; H01L 27/1288; H01L 21/02532; H01L 21/02592

(57) ABSTRACT

The present disclosure provides an array substrate, a manufacturing method thereof, and a display device. The array substrate comprises a gate electrode, a gate line, a data line, a gate insulating layer, an active layer, a source electrode and a drain electrode on a substrate. The gate electrode, the gate line and the data line are arranged on an identical layer, the gate line intersects the data line at a right angle, and the data line is disconnected at an intersection with the gate line. The source electrode and the drain electrode are arranged above the gate electrode, the gate line and the data line, and the disconnected data lines are connected via the source electrode.

### CROSS-REFERENCE TO RELATED APPLICATION

This application claims priority to Chinese Patent Application No. 201410048499.3 filed on Feb. 12, 2014, the disclosures of which are incorporated in their entirety by reference herein.

### TECHNICAL FIELD

The present invention relates to the field of display technology, in particular to an array substrate, manufacturing method thereof, and a display device.

### BACKGROUND

FIG. 1 is a schematic view showing a part of components of an existing thin film transistor (TFT) array substrate. In FIG. 1, 101 represents a substrate, 102 represents a gate line, 103 represents a gate insulating layer, 104 represents a data line, and 105 represents a passivation layer. The gate line 102 and the data line 104 are located at different layers.

Currently, a method for manufacturing the TFT array substrate mainly comprises the following steps.

S101: forming the gate line and a gate electrode on the substrate by a patterning process. This step may comprise depositing a gate metal layer film on the substrate, and then exposing, developing and etching it, so as to form patterns of the gate line and the gate electrode.

S102: forming the gate insulating layer on the gate line and the gate electrode.

S103: forming an active layer on the gate insulating layer by a patterning process. This step may comprise depositing a semiconductor layer film, and then exposing, developing and etching it, so as to form a pattern of the active layer.

S104: forming a source electrode, a drain electrode and the data line by a patterning process. This step may comprise depositing a source/drain metal layer film, and then exposing, developing and etching it, so as to form patterns of the source electrode, the drain electrode and the data line.

S105: forming the passivation layer (PVX) on the source electrode, the drain electrode and the data line, and forming a via-hole in the passivation layer by a patterning process, the drain electrode being connected to a pixel electrode formed subsequently through the via-hole.

S106: forming the pixel electrode on the passivation layer by a patterning process. This step may comprise depositing a metal oxide (ITO) film, and then exposing, developing and etching it, so as to form a pattern of the pixel electrode.

As shown in FIG. 1, the data line 104 and the gate line 102 are located at different layers and the data line 104 is merely protected by the passivation layer 105, so it is easily scratched by particles, and thereby it is easy to occur data line open. The data line open is a seriously undesirable phenomenon for the manufacture of a TFT liquid crystal display (TFT-LCD). Hence, it is an urgent problem to be solved in the art to reduce the possibility of the data line open for the TFT array substrate.

### SUMMARY

An object of embodiments of the present invention is to provide an array substrate, manufacturing method thereof, and a display device, so as to reduce the possibility of data line open for the array substrate.

In one aspect, the present disclosure provides an array substrate, comprising a gate electrode, a gate line, a data line, a gate insulating layer, an active layer, a source electrode and a drain electrode on a substrate. The gate electrode, the gate line and the data line are arranged on an identical layer, the gate line intersects the data line at a right angle, and the data line is disconnected at an intersection with the gate line. The source electrode and the drain electrode are arranged above the gate electrode, the gate line and the data line, and the disconnected data line is connected via the source electrode.

Alternatively, the gate electrode, the gate line and the data line are formed by a patterning process. Alternatively, the gate electrode, the gate line and the data line are arranged on the substrate. The gate insulating layer is arranged on the gate electrode, the gate line and the data line, and a first via-hole through which the source electrode is connected to the data line is formed in the gate insulating layer. The active layer is arranged on the gate insulating layer. The source electrode and the drain electrode are located on the active layer and the source electrode is connected to the data line through the first via-hole, so as to connect the disconnected data lines.

The array substrate further comprises a passivation layer which is located on the source electrode and the drain electrode and a second via-hole is formed in the passivation layer; and a pixel electrode located on the passivation layer and connected to the drain electrode via the second via-hole in the passivation layer.

In another aspect, the present disclosure provides a display device comprising the above-mentioned array substrate.

In yet another aspect, the present disclosure provides a method for manufacturing an array substrate, comprising the steps of:

forming a gate electrode, a gate line and a data line on a substrate by a patterning process, the gate line intersecting the data line at a right angle, and the data line being disconnected at an intersection with the gate line;

forming a gate insulating layer on the gate electrode, the gate line and the data line;

forming a first via-hole and an active layer on the gate insulating layer by a patterning process;

forming a source electrode and a drain electrode on the active layer by a patterning process, the source electrode being connected to the data line through the first via-hole so as to connect the disconnected data lines;

forming a passivation layer on the source electrode and the drain electrode, and forming a second via-hole on the passivation layer by a patterning process; and

forming a pixel electrode on the passivation layer by a patterning process, the pixel electrode being connected to the drain electrode through the second via-hole.

Alternatively, the step of forming the first via-hole and the active layer on the gate insulating layer by a patterning process comprises:

forming a semiconductor layer film on the insulating gate layer;

coating a photoresist onto the semiconductor layer film;

exposing and developing the photoresist with a half-exposure mask plate, so as to form a photoresist fully-reserved region corresponding to a region of the active layer, a photoresist fully-removed region corresponding to a region of the first via-hole, and a photoresist half-reserved region corresponding to the other regions;

removing the semiconductor layer film and the gate insulating layer in the photoresist fully-removed region by an etching process, so as to form the first via-hole;

removing the photoresist in the photoresist half-reserved region by an ashing process;

removing the semiconductor layer film in the photoresist half-reserved region by an etching process; and

peeling off the photoresist in the photoresist fully-reserved region, so as to reveal a pattern of the active layer.

Alternatively, the semiconductor layer includes an a-Si film and an n+a-Si film.

Alternatively, two first via-holes are provided in the gate insulating layer at a position where the data line is disconnected, and the two via-holes are each located at one end of the disconnected data line.

Alternatively, the source electrode is located above the position where the data line is disconnected, and connected to the data line through the two first via-holes in the gate insulating layer, the disconnected data lines are connected together by means of the source electrode.

The present disclosure has the following advantageous effects. The data line is arranged on an identical layer to the gate line and located on a lower layer. As compared with the prior art where the data line is located on an upper layer, the data line of the present disclosure is not easily scratched. As a result, it is able to reduce the possibility of data line disconnection.

In addition, the gate line and the data line are formed simultaneously by a patterning process. As compared with the prior art where the gate line and the data line are formed separately, merely one patterning process is required. As a result, it is able to simplify the procedure of manufacturing the TFT array substrate, and further reduce the possibility of data line disconnection.

### BRIEF DESCRIPTION OF THE DRAWINGS

FIG. 1 is a schematic view showing a part of components of a TFT array substrate manufactured by an existing process;

FIGS. 2A-2F are flow charts of a method for manufacturing a TFT array substrate according to one embodiment of the present invention;

FIGS. 3A-3G are flow charts of a process for forming an active layer according to one embodiment of the present invention; and

FIG. 4 is a schematic view showing a part of components of the TFT array substrate manufactured by the method according to one embodiment of the present invention.

### DETAILED DESCRIPTION

To make the objects, the technical solutions and the advantages of the present invention more apparent, the present invention will be described hereinafter in conjunction with the drawings and the embodiments.

An embodiment of the present invention provides a TFT array substrate comprising a gate electrode, a gate line, a data line, a gate insulating layer, an active layer, a source electrode and a drain electrode on a substrate. The gate electrode, the gate line and the data line are arranged on an identical layer, the gate line intersects the data line at a right angle, and the data line is disconnected at an intersection with the gate line. The source electrode and the drain electrode are arranged above the gate electrode, the gate line and the data line, and the disconnected data line is reconnected via the source electrode.

The substrate in the embodiment may be a substrate alone, or a substrate provided with the other components.

In the TFT array substrate, the gate line and the data line are arranged on an identical layer, and the data line is arranged on a lower layer. As compared with the prior art where the data line is located on an upper layer, the data line of embodiments of the present invention is not easily scratched. As a result, it is able to reduce the possibility of data line disconnection.

Alternatively, the TFT array substrate may comprise:

the substrate;

the gate electrode, the gate line and the data line arranged on an identical layer on the substrate, the gate line intersecting the data line at a right angle, and the data line being disconnected at an intersection with the gate line;

the gate insulating layer arranged on the gate electrode, the gate line and the data line, a first via-hole connecting the source electrode and the data line being arranged on the gate insulating layer;

the active layer arranged on the gate insulating layer;

the source electrode and the drain electrode arranged on the active layer and connected to the data line through the first via-hole, so as to connect the disconnected data lines;

a passivation layer located on the source electrode and the drain electrode, a second via-hole being formed in the passivation layer; and

a pixel electrode located on the passivation layer and connected to the drain electrode via the second via-hole in the passivation layer.

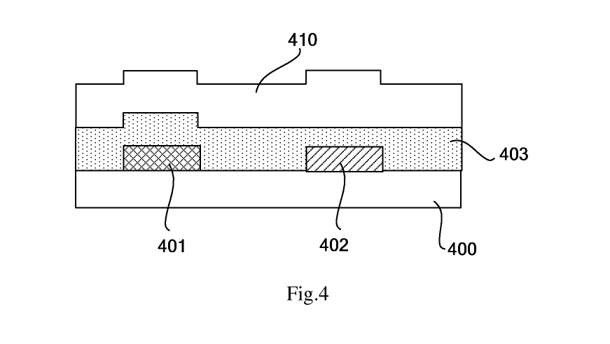

Referring to FIG. 4, which is a schematic view showing a part of components of the TFT array substrate according to one embodiment of the present invention, the gate line 401 and the data line 402 of the TFT array substrate are arranged on an identical layer, and two protection layers, i.e., the gate insulating layer 403 and the passivation layer 410, are arranged on the data line 402. As compared with the prior art where the data line is protected merely by the passivation layer, the data line of embodiments of the present invention is not easily scratched, and as a result, it is able to reduce the possibility of data line disconnection.

Alternatively, the gate line and the data line are formed by a patterning process. As compared with the prior art where the gate line and the data line are formed separately, merely one patterning process is required. As a result, it is able to simplify the procedure of manufacturing the TFT array substrate, and further reduce the possibility of data line disconnection.

An embodiment of the present invention further provides a display device comprising the above-mentioned TFT array substrate. The display device may be any products or members having a display function, such as a liquid crystal panel, an electronic paper, an OLED panel, a mobile phone, a tablet PC, a TV, a display, a laptop PC, a digital photo frame and a navigator.

The present disclosure further provides a method for manufacturing a TFT array substrate, comprising the steps of:

S201: forming a gate electrode, a gate line and a data line on a substrate simultaneously by a patterning process, the gate line intersecting the data line at a right angle, and the data line being disconnected at an intersection with the gate line;

S202: forming a gate insulating layer on the gate electrode, the gate line and the data line;

S203: forming a first via-hole and an active layer on the gate insulating layer by a patterning process;

S204: forming a source electrode and a drain electrode on the active layer by a patterning process, the source electrode being connected to the data line through the first via-hole so as to connect the disconnected data lines;

S205: forming a passivation layer on the source electrode and the drain electrode, and forming a second via-hole on the passivation layer by a patterning process; and

S206: forming a pixel electrode on the passivation layer by a patterning process, the pixel electrode being connected to the drain electrode through the second via-hole.

In this embodiment, two protection layers, i.e., the gate insulating layer and the passivation layer, are arranged above the data line. As compared with the prior art where the data line is merely protected by the passivation layer, the data line of embodiments of the present invention is not easily scratched. As a result, it is able to reduce the possibility of data line disconnection.

In addition, the gate line and the data line are formed simultaneously by a patterning process. As compared with the prior art where the gate line and the data line are formed separately, merely one patterning process is required. As a result, it is able to simplify the procedure of manufacturing the TFT array substrate, and further reduce the possibility of data line disconnection.

In S203, the first via-hole and the active layer may be formed on the gate insulating layer by a patterning process, and this step may comprise the following steps:

S2031: forming a semiconductor layer film on the insulating gate layer;

S2032: coating a photoresist onto the semiconductor layer film;

S2033: exposing and developing the photoresist with a half-exposure mask plate, so as to form a photoresist fully-reserved region corresponding to a region of the active layer, a photoresist fully-removed region corresponding to a region of the first via-hole, and a photoresist half-reserved region corresponding to the other regions which are regions other than the photoresist fully-reserved region and the photoresist fully-removed region;

S2034: removing the semiconductor layer film and the gate insulating layer in the photoresist fully-removed region by an etching process, so as to form the first via-hole;

S2035: removing the photoresist in the photoresist half-reserved region by an ashing process;

S2036: removing the semiconductor layer film in the photoresist half-reserved region by an etching process; and

S2037: peeling off the photoresist in the photoresist fully-reserved region, so as to reveal a pattern of the active layer.

The semiconductor layer film may comprise an a-Si film and an n+ a-Si film. Of course, it may also be a polysilicon film.

The first via-hole and the active layer are formed on the gate insulating layer by a patterning process. As a result, it is able to reduce the number of times a mask process, thereby to further simplify the procedure.

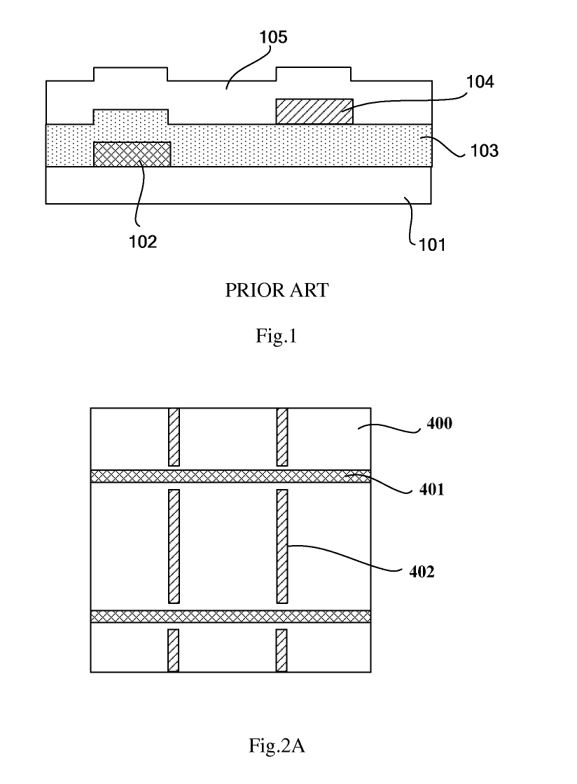

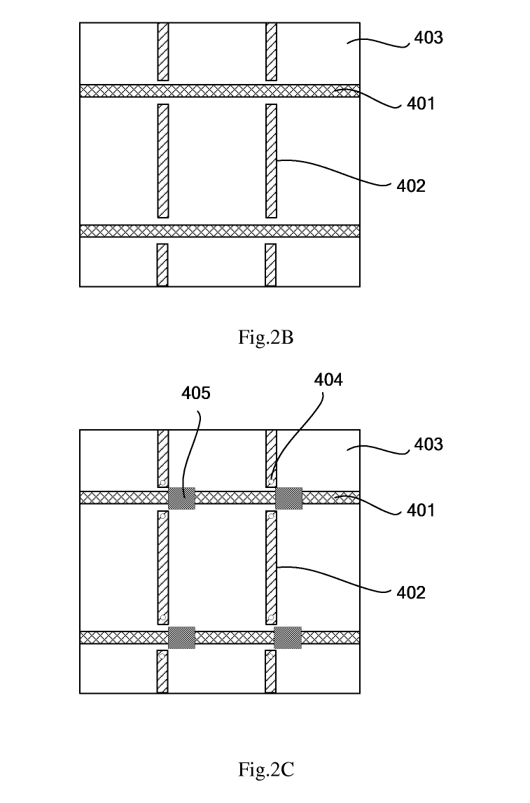

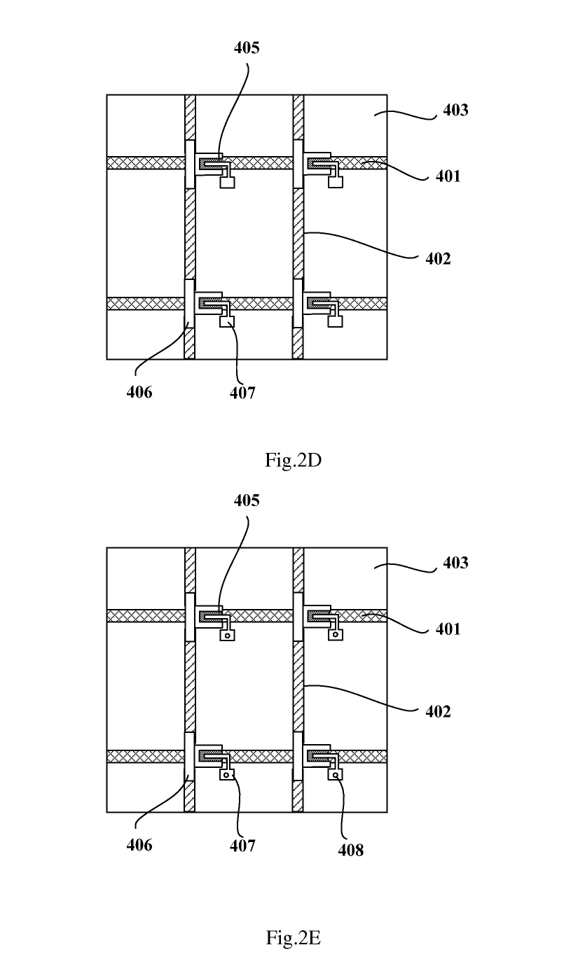

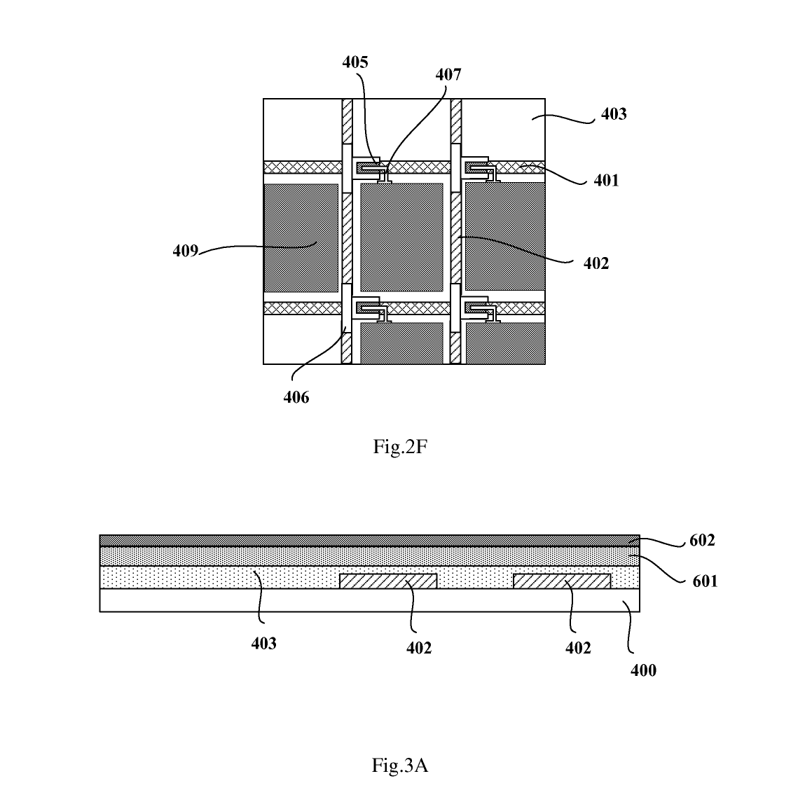

Referring to FIGS. 2A-2F, which are flow charts of the method for manufacturing the TFT array substrate according to one embodiment of the present invention, the method comprises the following steps.

Step 1: referring to FIG. 2A, forming a gate electrode (not shown), the gate line 401 and the data line 402 on the substrate 400 simultaneously by a patterning process, the gate line 401 intersecting the data line 402 at a right angle, and the data line 402 being disconnected at an intersection with the gate line 401.

To be specific, a gate metal layer film is deposited at first, and then exposed, developed and etched, so as to form the gate electrode, the gate line 401 and the data line 402 simultaneously.

Step 2: referring to FIG. 2B, forming the gate insulating layer 403 on the gate electrode, the gate line 401 and the data line 402.

To be specific, the gate insulating layer 403 may be formed by deposition.

Step 3: referring to FIG. 2C, forming the first via-hole 404 and the active layer 405 on the gate insulating layer 403 by a patterning process.

Two first via-holes 404 are provided in the gate insulating layer 403 at a position where the data line 402 is disconnected, and they are each located at one end of the disconnected data line 402.

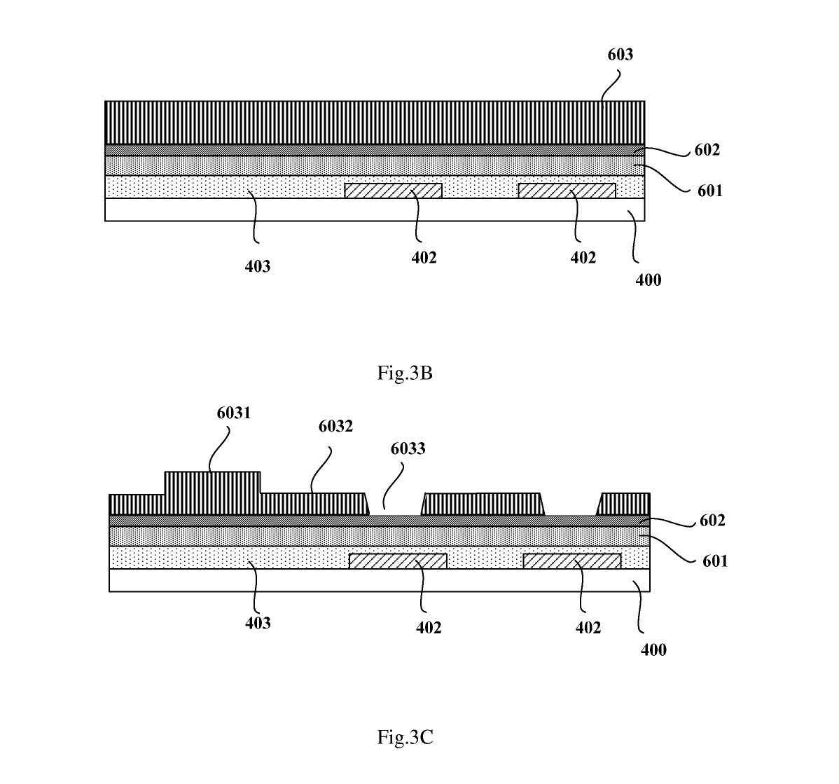

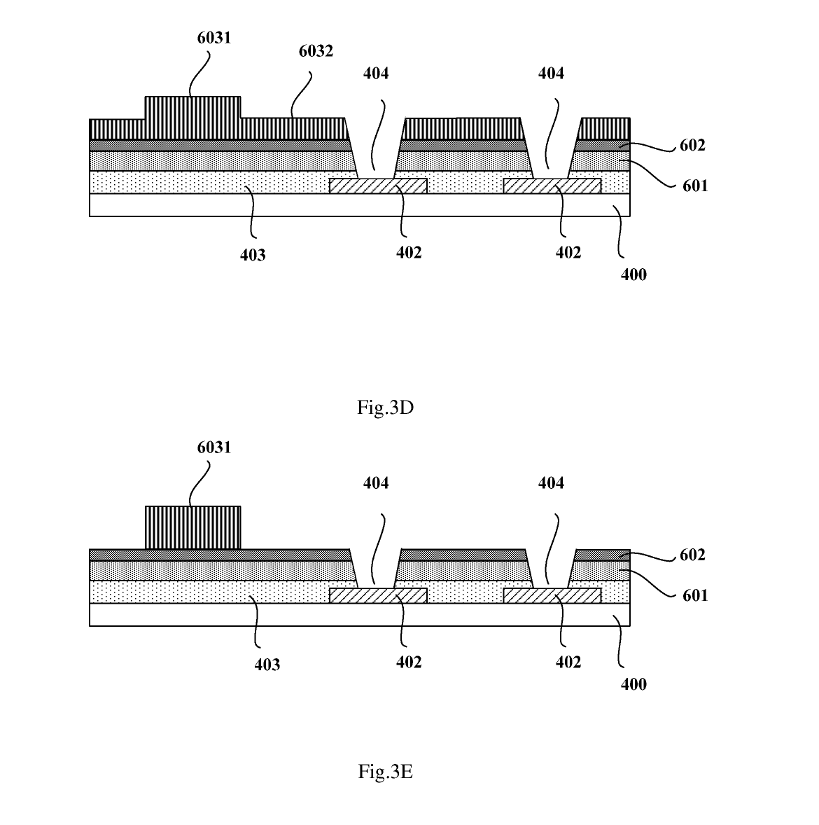

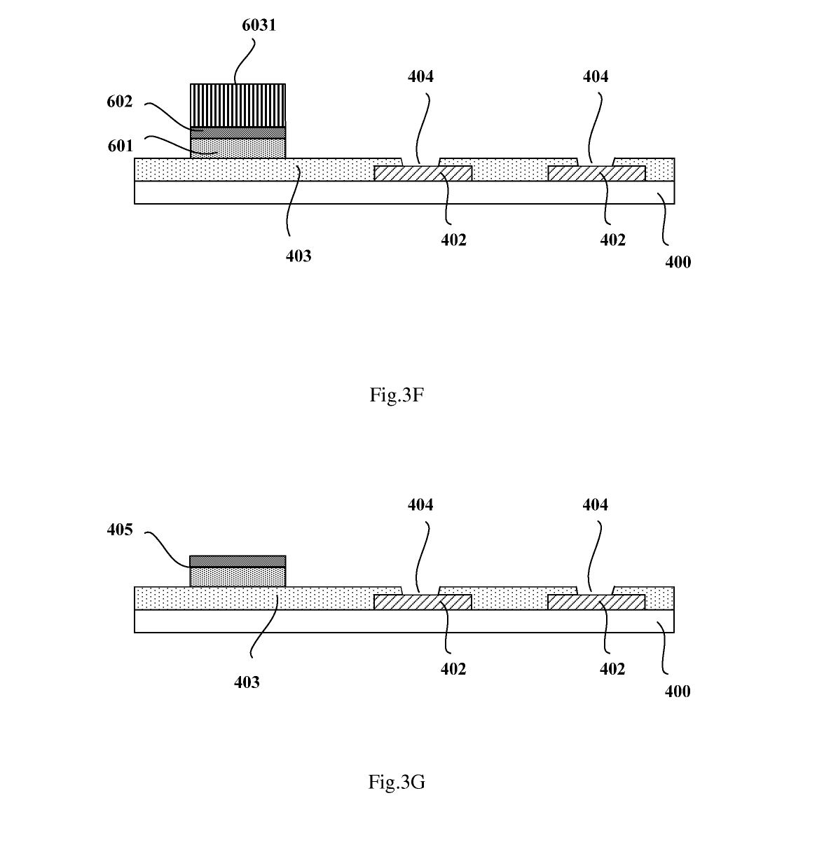

Referring to FIGS. 3A-3G, which are flow charts of a process for forming the active layer according to one embodiment of the present invention, the process may comprise the following steps:

S501: referring to FIG. 3A, forming an a-Si film 601 and an n+ a-Si film 602 on the gate insulating layer 403;

S502: referring to FIG. 3B, coating a photoresist 603 onto the n+ a-Si film 602;

S503: referring FIG. 3C, exposing and developing the photoresist 603 with a half-exposure mask plate, so as to form a photoresist fully-reserved region 6031 corresponding to a region of the active layer, a photoresist fully-removed region 6033 corresponding to a region of the first via-hole, and a photoresist half-reserved region 6032 corresponding to the other regions;

S504: referring to FIG. 3D, removing the a-Si film, the n+ a-Si film and the gate insulating layer in the photoresist fully-removed region 6033 by an etching process, so as to form the first via-hole 404;

S505: referring to FIG. 3E, removing the photoresist in the photoresist half-reserved region 6032 by an ashing process;

S506: referring to FIG. 3F, removing the a-Si film and the n+ a-Si film in the photoresist half-reserved region 6032 by an etching process; and

S507: referring to FIG. 3G, peeling off the photoresist in the photoresist fully-reserved region 6031, so as to reveal a pattern of the active layer 405.

Step 4: referring to FIG. 2D, forming the source electrode 406 and the drain electrode 407 on the active layer 405 by a patterning process, the source electrode 406 being connected to the data line 402 via the first via-hole 404 in the gate insulating layer 403, so as to connect the disconnected data lines 402.

The source electrode 406 is located above the position where the data line 402 is disconnected, and connected to the data line 402 through the first via-holes 404 in the gate insulating layer 403. The disconnected data lines 402 are connected together by means of the source electrode 406.

Step 5: referring FIG. 2E, forming the passivation layer (not shown) on the source electrode 406 and the drain electrode 407, and forming the second via-hole in the passivation layer by a patterning process.

Step 6: referring to FIG. 2F, forming a pixel electrode 409 on the passivation layer by a patterning process, the pixel electrode 409 being connected to the drain electrode 407 through the second via-hole 408 in the passivation layer.

The pixel electrode 410 may be made of an ITO material.

In the above embodiment, the method for manufacturing the TFT array substrate is described by taking an array substrate with a twisted nematic (TN) mode as an example. Of course, this method may also be applicable to an array substrate with an advanced super dimension switch (ADS) mode or a vertical alignment (VA) mode.

The above are merely the preferred embodiments of the present invention. It should be appreciated that, a person skilled in the art may make further improvements and modifications without departing from the principle of the present invention, and these improvements and modifications shall also be considered as the scope of the present invention.

What is claimed is:

1. An array substrate, comprising a gate electrode, a gate line, a data line, a gate insulating layer, an active layer, a source electrode and a drain electrode on a substrate, wherein
the gate electrode, the gate line and the data line are arranged on an identical layer, the gate line intersects the data line at a right angle, and the data line is disconnected at an intersection with the gate line, and
the source electrode and the drain electrode are arranged above the gate electrode, the gate line and the data line, and the disconnected data line is connected via the source electrode.

2. The array substrate according to claim 1, wherein
the gate electrode, the gate line and the data line are formed by a patterning process.

3. The array substrate according to claim 1, wherein
the gate electrode, the gate line and the data line are arranged on the substrate,
the gate insulating layer is arranged on the gate electrode, the gate line and the data line, and a first via-hole through which the source electrode is connected to the data line is formed in the gate insulating layer,
the active layer is arranged on the gate insulating layer, and
the source electrode and the drain electrode are located on the active layer and the source electrode is connected to the data line through the first via-hole, so as to connect the disconnected data lines.

4. The array substrate according to claim 1, further comprising:
a passivation layer which is located on the source electrode and the drain electrode and a second via-hole is formed in the passivation layer; and
a pixel electrode located on the passivation layer and connected to the drain electrode via the second via-hole in the passivation layer.

5. A display device comprising an array substrate, the array substrate comprises a gate electrode, a gate line, a data line, a gate insulating layer, an active layer, a source electrode and a drain electrode on a substrate, wherein
the gate electrode, the gate line and the data line are arranged on an identical layer, the gate line intersects the data line at a right angle, and the data line is disconnected at an intersection with the gate line, and
the source electrode and the drain electrode are arranged above the gate electrode, the gate line and the data line, and the disconnected data line is connected via the source electrode.

6. The display device according to claim 5, wherein
the gate electrode, the gate line and the data line are formed by a patterning process.

7. The display device according to claim 5, wherein
the gate electrode, the gate line and the data line are arranged on the substrate,
the gate insulating layer is arranged on the gate electrode, the gate line and the data line, and a first via-hole through which the source electrode is connected to the data line is formed in the gate insulating layer,
the active layer is arranged on the gate insulating layer, and
the source electrode and the drain electrode are located on the active layer and the source electrode is connected to the data line through the first via-hole, so as to connect the disconnected data lines.

8. The display device according to claim 5, the array substrate further comprises:
a passivation layer which is located on the source electrode and the drain electrode and a second via-hole is formed in the passivation layer; and
a pixel electrode located on the passivation layer and connected to the drain electrode via the second via-hole in the passivation layer.

9. A method for manufacturing an array substrate, comprising the steps of:
forming a gate electrode, a gate line and a data line on a substrate by a patterning process, the gate line intersecting the data line at a right angle, and the data line being disconnected at an intersection with the gate line;
forming a gate insulating layer on the gate electrode, the gate line and the data line;
forming a first via-hole and an active layer on the gate insulating layer by a patterning process;
forming a source electrode and a drain electrode on the active layer by a patterning process, the source electrode being connected to the data line through the first via-hole so as to connect the disconnected data lines;
forming a passivation layer on the source electrode and the drain electrode, and forming a second via-hole on the passivation layer by a patterning process; and
forming a pixel electrode on the passivation layer by a patterning process, the pixel electrode being connected to the drain electrode through the second via-hole.

10. The method according to claim 9, wherein the step of forming the first via-hole and the active layer on the gate insulating layer by a patterning process comprises:
forming a semiconductor layer film on the insulating gate layer;
coating a photoresist onto the semiconductor layer film;
exposing and developing the photoresist with a half-exposure mask plate, so as to form a photoresist fully-reserved region corresponding to a region of the active layer, a photoresist fully-removed region corresponding to a region of the first via-hole, and a photoresist half-reserved region corresponding to the other regions;
removing the semiconductor layer film and the gate insulating layer in the photoresist fully-removed region by an etching process, so as to form the first via-hole;
removing the photoresist in the photoresist half-reserved region by an ashing process;
removing the semiconductor layer film in the photoresist half-reserved region by an etching process; and
peeling off the photoresist in the photoresist fully-reserved region, so as to reveal a pattern of the active layer.

11. The method according to claim 10, wherein the semiconductor layer film comprises an a-Si film and an n+ a-Si film.

12. The method according to claim 9, wherein, two first via-holes are provided in the gate insulating layer at a position where the data line is disconnected, and the two via-holes are each located at one end of the disconnected data line.

13. The method according to claim 12, wherein, the source electrode is located above the position where the data line is disconnected, and the source electrode is connected to the data line through the two first via-holes in the gate insulating layer, the disconnected data lines are connected together by means of the source electrode.
